(19) United States
(12) Patent Application Publication
(10) Pub. No.: US 2009/0139758 A1
(43) Pub. Date: Jun. 4, 2009

(54) Printed circuit board assembly and manufacturing method for the same

(75) Inventors: Hyo Young Shin, Suwon-si (KR); Seung Boo Jung, Seoul (KR); Young Jun Moon, Suwon-si (KR); Soon Min Hong, Seoul (KR); Chang Yong Lee, Suwon-si (KR); Ja Myeong Koo, Incheon (KR); Hyun Tae Kim, Daegu (KR); Jong Bum Lee, Seoul (KR); Hyun Joo Han, Suwon-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRONICS CO., LTD., Suwon-si (KR)

(21) Appl. No.: 12/155,401

(22) Filed: Jun. 3, 2008

(30) Foreign Application Priority Data
Nov. 29, 2007 (KR) 10-2007-122418

(51) Int. Cl. H05K 3/36; H01R 12/04

(52) U.S. Cl. 174/261; 29/830

(57) ABSTRACT

A printed circuit board (PCB) assembly is disclosed, which includes a first PCB on which a plurality of first electrode terminals are arranged at intervals from one another; a second PCB on which a plurality of second electrode terminals respectively connected with the first electrode terminals are arranged at intervals from one another; and separation preventing member which prevents the first and the second electrode terminals from deviating from their correct positions when the first and the second electrode terminals are ultrasonically-welded to each other. Accordingly, lateral movement of the first and the second PCBs relative to each other is restricted owing to the separation preventing member, the plurality of first electrode terminals and second electrode terminals can be bonded to each other without deviating from their correct positions.

### CROSS-REFERENCE TO RELATED APPLICATIONS

This application claims the priority benefit of Korean Patent Application No. 2007-122418, filed on Nov. 29, 2007, in the Korean Intellectual Property Office, the disclosure of which is incorporated herein by reference.

### BACKGROUND

1. Field

The present invention relates to a printed circuit board (PCB) assembly and a manufacturing method for the same. More particularly, the present invention relates to a PCB assembly including a pair of PCBs each including a plurality of electrode terminals bonded to the electrode terminals of the other PCB, and a manufacturing method for the same.

2. Description of the Related Art

Generally, a printed circuit board (PCB) assembly is installed in a variety of electronic devices to control the operation of the electronic devices. Such a PCB assembly includes a pair of PCBs each equipped with a plurality of electrode terminals and bonded to each other through the electrode terminals.

In a conventional PCB assembly, the electrode terminals are indirectly connected to each other through connectors or directly bonded by soldering or using an adhesive. When using the connectors, however, it is difficult to automate the manufacturing process due to a complicated shape of the connector. When using soldering, the PCB may be damaged by soldering heat applied thereto. Also, when using the adhesive, reliability in maintaining a long-term bond is deteriorated.

Recently, a PCB assembly has been suggested which includes a first PCB including first electrode terminals arranged at intervals from one another, and a second PCB including second electrode terminals respectively connected with the first electrode terminals, where the first and the second PCBs are bonded and connected to each other through ultrasonic welding, as disclosed in Korean Patent Registration No. 10-0711585. In other words, by directly bonding and connecting the first electrode terminals formed on the first PCB to the second electrode terminals formed on the second PCB through ultrasonic welding, damage of the PCB by heat can be prevented while improving reliability in a long-term bond between the first and the second electrode terminals.

In accordance with a tendency to miniaturization of the various electronic devices, size of the PCB assembly is also being reduced more and more. Therefore, in the conventional PCB assembly as described above, the intervals among the electrode terminals are preferably reduced so that a greater number of electrode terminals can be arranged in a small area.

However, when the intervals among the electrode terminals are reduced to less than a predetermined degree, the first electrode terminals and the second electrode terminals may be deviated from their correct (desired) positions while being bonded through ultrasonic welding. Accordingly, it is difficult to manufacture the PCB assembly to be smaller than a predetermined size.

In addition, in the conventional PCB assembly, if the first and the second electrode terminals are bonded to each other as deviated from the correct positions during the ultrasonic welding, a bonded surface area between the electrode terminals is decreased, thereby deteriorating durability at the bonded part. Furthermore, electric resistance is increased.

Moreover, when the intervals among the electrode terminals are too small, it is also difficult to exactly arrange the first and the second electrode terminals to correspond to each other.

### SUMMARY

Embodiments of the present invention have been made in order to solve the above problems. It is an aspect of the present invention to provide a printed circuit board (PCB) assembly capable of reducing intervals among electrode terminals of a PCB, and a manufacturing method for the same.

Another aspect of the invention is to provide a PCB assembly capable of preventing first and second electrode terminals from being deviated from their correct positions when being bonded to each other so that a bonded surface area between the first and the second electrode terminals is not reduced, and a manufacturing method for the same.

Still another aspect of the invention is to provide a PCB assembly capable of facilitating arrangement of the first and the second electrode terminals, and a manufacturing method for the same.

Consistent with one aspect, an exemplary embodiment of the present invention provides a printed circuit board (PCB) assembly including a first PCB on which a plurality of first electrode terminals are arranged at intervals from one another; a second PCB on which a plurality of second electrode terminals respectively connected with the first electrode terminals are arranged at intervals from one another; and separation preventing member which prevents the first and the second electrode terminals from deviating from their correct positions when the first and the second electrode terminals are ultrasonically welded to each other.

The separation preventing member may be projected from the first PCB among the plurality of first electrode terminals or from the second PCB among the plurality of second electrode terminals to be inserted in spaces among the second electrode terminals or among the first electrode terminals.

In addition, thickness of the separation preventing member may be formed to be greater than thickness of the first electrode terminal but less than the sum of the thickness of the first electrode terminal and thickness of the second electrode terminal.

The thickness of the separation preventing member may be the same as the sum of the thickness of the first electrode terminal and the thickness of the second electrode terminal.

Width of the first electrode terminal may be greater than width of the second electrode terminal.

The separation preventing member may partially cover both upper sides of the second electrode terminal with respect to a width direction.

The width of the separation preventing member may be the same as the interval between respective two neighboring first electrode terminals.

The width of the separation preventing member is less than the interval between two neighboring first electrode terminals so that the separation preventing member is spaced apart from lateral sides of two neighboring first electrode terminals.

Consistent with another aspect, an exemplary embodiment of the present invention provides a manufacturing method for a PCB assembly including forming a plurality of electrode terminals on each of a pair of PCBs; forming at least one separation preventing member; superposing the pair of PCBs on each other; and bonding the plurality of electrode terminals formed on the pair of PCBs to each other through ultrasonic welding.

During the forming of the electrode terminals on the pair of PCBs, a plurality of first electrode terminals may be formed on a first PCB at intervals from one another and a plurality of second electrode terminals are formed on a second PCB at intervals from one another.

During the forming of the separation preventing member, the separation preventing member may be formed on at least one of the first PCB among the first electrode terminals and the second PCB among the second electrode terminals.

The separation preventing member may be formed to be thicker than the first electrode terminals and the second electrode terminals.

During the superposing of the pair of PCBs on each other, the separation preventing member may be inserted in spaces among the plurality of first electrode terminals of the first PCB or among the plurality of second electrode terminals of the second PCB, and the first electrode terminals and the second electrode terminals are disposed to face each other.

During the bonding of the plurality of electrode terminals formed on the pair of PCBs to each other through ultrasonic welding, the plurality of first electrode terminals and the plurality of second electrode terminals are bonded respectively to each other.

During the forming of the separation preventing member, thickness of the separation preventing member may be the same as the sum of thickness of the first electrode terminal and thickness of the second electrode terminal, and during the bonding of the electrode terminals through ultrasonic welding, the separation preventing member may be bonded to any one of the first PCB and the second PCB through ultrasonic welding.

In an aspect of the present invention, there is provided a printed circuit board (PCB) assembly including a first PCB on which a plurality of first electrode terminals are arranged at intervals from one another; a second PCB on which a plurality of second electrode terminals are arranged at intervals from one another; and a separation preventing member which prevents the first and the second electrode terminals from deviating from their correct positions when the first and the second electrode terminals are ultrasonically welded to each other.

In an aspect of the present invention, there is provided a manufacturing method for a printed circuit board (PCB) assembly including forming a plurality of electrode terminals on each of a pair of PCBs; forming a separation preventing member on the first PCB among the first electrode terminals or the second PCB among the second electrode terminals; superposing the pair of PCBs on each other; and bonding the plurality of electrode terminals formed on the pair of PCBs to each other through ultrasonic welding.

In an aspect of the present invention, there is provided a manufacturing method for a printed circuit board (PCB) assembly including forming at least one separation preventing member on a first PCB among first electrode terminals or a second PCB among second electrode terminals; superposing the first and second PCBs on each other; and bonding the plurality of electrode terminals formed on the pair of PCBs to each other through ultrasonic welding.

In an aspect of the present invention, there is provided a printed circuit board (PCB) assembly including a first PCB on which a plurality of first electrode terminals are arranged at intervals from one another; a second PCB on which a plurality of second electrode terminals are arranged at intervals from one another; and a plurality of separation preventing members which prevent the first and the second electrode terminals from deviating from their correct positions when the first and the second electrode terminals are ultrasonically welded to each other.

### BRIEF DESCRIPTION OF THE DRAWINGS

These and/or other aspects, features, and advantages of exemplary embodiments of the invention will become apparent and more readily appreciated from the following description of exemplary embodiments, taken in conjunction with the accompanying drawings, of which:

FIG. 1 and FIG. 2 are sectional views of a printed circuit board (PCB) assembly according to a first exemplary embodiment of the present invention;

FIG. 3 is a flowchart illustrating a manufacturing method for the PCB according to an exemplary embodiment of the present invention;

FIG. 4 is a sectional view of a PCB assembly according to a second exemplary embodiment of the present invention;

FIG. 5 is a sectional view of a PCB assembly according to a third exemplary embodiment of the present invention; and

FIG. 6 is a sectional view of a PCB assembly according to a fourth exemplary embodiment of the present invention.

### DETAILED DESCRIPTION OF EMBODIMENTS

Reference will now be made in detail to exemplary embodiments of the present invention, examples of which are illustrated in the accompanying drawings, wherein like reference numerals refer to like elements throughout.

A first exemplary embodiment of the present invention will be described below by referring to the drawings.

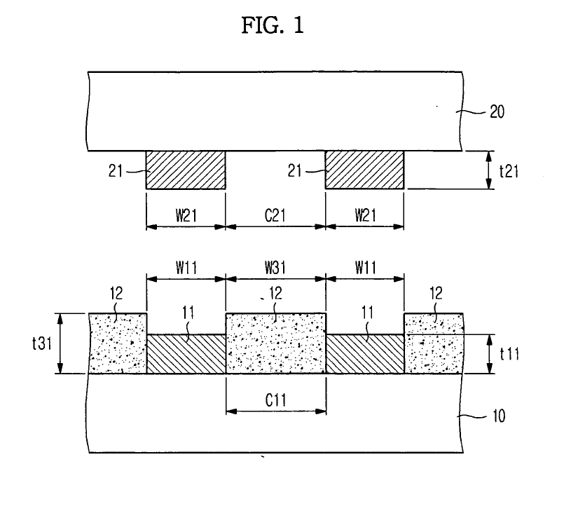

As shown in FIG. 1, a printed circuit board (PCB) assembly includes a first PCB 10 on which a plurality of first electrode terminals 11 are arranged at intervals, and a second PCB 20 on which a plurality of second electrode terminals 21 are arranged at intervals to be connected with the first electrode terminals respectively. Here, at least one of the first PCB 10 and the second PCB 20 is made of a flexible substrate whereas the other one may be made of a flexible substrate, a rigid substrate, a ceramic substrate or a glass substrate.

The pluralities of first electrode terminals 11 and second electrode terminals 21 formed on the first PCB 10 and the second PCB 20, respectively, have a predetermined thickness to be bonded and connected to each other by ultrasonic welding. According to this embodiment, the second PCB 20 is disposed at an upper part of the first PCB 10, the first exemplary electrode terminals 11 are formed on an upper surface of the first PCB 10, and the second electrode terminals 21 are formed on a lower surface of the second PCB 20. In order for efficient bonding between the first and the second electrode terminals 11 and 21 through ultrasonic welding, any one of the first and the second electrode terminals 11 and 21 is plated with tin while the other one is plated with nickel or gold.

Also, at least one between the first and the second electrode terminals 11 and 21 may be deviated from their correct positions during bonding to each other through ultrasonic welding, thereby causing an inexact bonding. To prevent this, the PCB assembly according to the present invention is provided with separation preventing members 12.

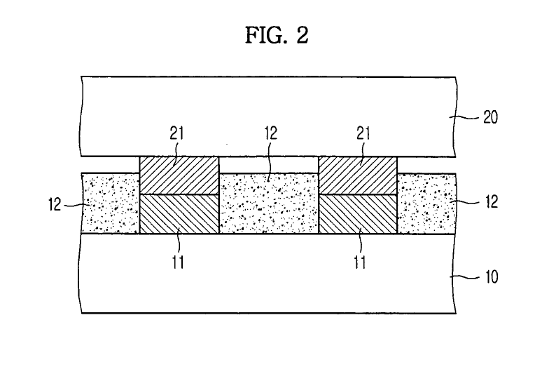

The separation preventing members 12 are projected from the first PCB 10 among the plurality of first electrode terminals 11. A thickness t31 of each separation preventing member is designed to be greater than a thickness of the first electrode terminals 11 but not greater than the sum of a thickness t11 of the first electrode terminal 11 and a thickness t21 of the second electrode terminal 21. For bonding between the first and the second electrode terminals 11 and 21, the first PCB 10 and the second PCB are superposed on each other in the manner that upper ends of the first electrode terminals 11 and lower ends of the second electrode terminals 21 contact each other, respectively, as shown in FIG. 2. Accordingly, during this, the separation preventing members 12 can be inserted in spaces among the second electrode terminals 21.

In the first exemplary embodiment of the present invention, the thickness t31 of the separation preventing member 12 is less than the sum t11+t21. A width W11 of the first electrode terminal 11 and a width W21 of the second electrode terminal 21 are substantially the same. Also, an interval C11 between respective two neighboring first electrode terminals 11 and an interval C21 between respective two neighboring second electrode terminals 21 are substantially the same as each other. A width W31 of the separation preventing member 12 is designed to be substantially the same as the interval C11 between two neighboring first electrode terminals 11 such that both lateral sides of the separation preventing member 12 are in contact with lateral sides of the two neighboring first electrode terminals 11.

Hereinafter, a method for manufacturing the above-structured PCB assembly will be explained.

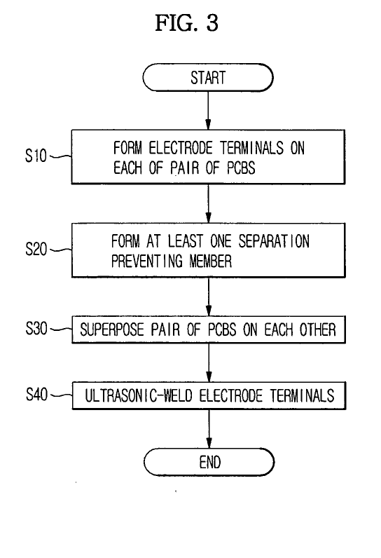

As shown in the flowchart of FIG. 3, the manufacturing method of the PCB assembly according to the exemplary embodiment of the present invention includes operations of forming a plurality of the electrode terminals 11 and 21 respectively on a pair of the PCBs 10 and 20 (S10), forming at least one separation preventing member 12 (S20), arranging the pair of PCBs 10 and 20 to be superposed on each other (S30), and bonding the plurality of electrode terminals 11 and 21 of the first and the second PCBs 10 and 20 respectively to each other by ultrasonic welding (S40).

In the operation of forming the plurality of electrode terminals 11 and 21 on the pair of PCBs 10 and 20 (S10) in an exemplary embodiment shown in FIGS. 1 and 2, the plurality of first electrode terminals 11 are arranged at intervals on the first PCB 10 and the plurality of second electrode terminals 12 on the second PCB 20. In the operation of forming the separation preventing members 12 (S20), the separation preventing members 12 are formed among the plurality of first electrode terminals 11 of the first PCB 10 or among the plurality of second electrode terminals 21 of the second PCB 20, by a relatively greater thickness than one of the electrode terminals 11 and 21. According to this exemplary embodiment, the separation preventing members 12 are projected from the first PCB 10 among the first electrode terminals 11.

During the operation of arranging the first and the second PCBs 10 and 20 to be superposed on each other (S30), the separation preventing members 12 are inserted in spaces among the first electrode terminals 11 of the first PCB 10 or spaces among the second electrode terminals 21 of the second PCB 20. According to this exemplary embodiment, since being protruded from the first PCB 10 among the first electrode terminals 11, the separation preventing members 12 are inserted in the spaces among the second electrode terminals 21 when the first and the second PCBs 10 and 20 are superposed on each other.

When the separation preventing members 12 protruded among the first electrode terminals 11 are thus inserted in the spaces among the second electrode terminals 21, the first electrode terminals 11 and the second electrode terminals 21 can be positioned to exactly correspond to each other due to the existence of the separation preventing members 12. As a result, arrangement of the first and the second electrode terminals 11 and 21 can be easily achieved.

After the first and the second electrode terminals 11 and 21 are well arranged by the separation preventing members 12, the operation of bonding the electrode terminals 11 and 21 of the first and the second PCBs 10 and 20 through ultrasonic welding (S40) is performed. Therefore, although a force is exerted in any lateral direction to the first and the second PCBs 10 and 20 during the ultrasonic welding, the first and the second PCBs 10 and 20 are restricted in lateral movement relative to each other due to the separation preventing members 12 engaged with the lateral sides of the second electrode terminals 21. Consequently, the bonding between the plurality of first and second electrode terminals 11 and 21 can be performed at correct positions.

In addition, as the first and the second electrode terminals 11 and 21 are thus bonded through the correct positions to each other, a bonded surface area between the first and the second electrode terminals 11 and 21 can be maximized. As a result, deterioration of durability and increase of electric resistance which may occur at the bonded part can be prevented.

Although the present exemplary embodiment has been explained, for the sake of convenience, to include the second PCB 20 disposed at the upper part of the first PCB 10, the first PCB 10 including the first electrode terminals 11 and the separation preventing members 12 projected on the upper surface thereof, and the second PCB 20 including the second electrode terminals 21 projected on the lower surface thereof, the PCB assembly according to the present invention may be structured such that the first PCB 10 is disposed at an upper part of the second PCB 20, the first electrode terminals 11 and the separation preventing members 12 are projected on a lower surface of the first PCB 10, and the second electrode terminals 21 are projected on an upper surface of the second PCB 20.

Also, although the separation preventing members 12 are provided only to the first PCB 10 in this exemplary embodiment, the present invention is not limited to the depicted structure. That is, the separation preventing members 12 may be formed only at the second PCB 20 or at both the first and the second PCBs 10 and 20.

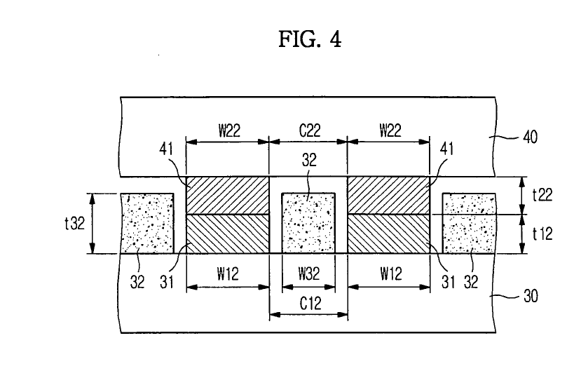

According to the first exemplary embodiment of the present invention, in addition, the width W31 of the separation preventing member 12 is the same as the interval C11 between the first electrode terminals 11. However, the present invention is not limited to this. For example, FIG. 4 shows a first printed circuit board 30 having first electrode terminals 31 with widths W12 and a second printed circuit board 40 having second electrode terminals 41 with widths W22. According to a second exemplary embodiment of the present invention, a width W32 of a separation preventing member 32 may be formed less than an interval C12 between respective two neighboring a plurality of first electrode terminals 31 such that each of the separation preventing members 32 is spaced apart from lateral sides of two neighboring first electrode terminals 31, as shown in FIG. 4. In addition, the width W32 in this exemplary embodiment is less than the width of an interval C22 between second electrode terminals 41. In the second exemplary embodiment, a thickness t32 of the separation preventing member 32 is formed to be greater than a thickness t12 of the first electrode terminal 31 but less than the sum of the thickness t12 of the first electrode terminal 31 and a thickness t22 of the second electrode terminal 41.

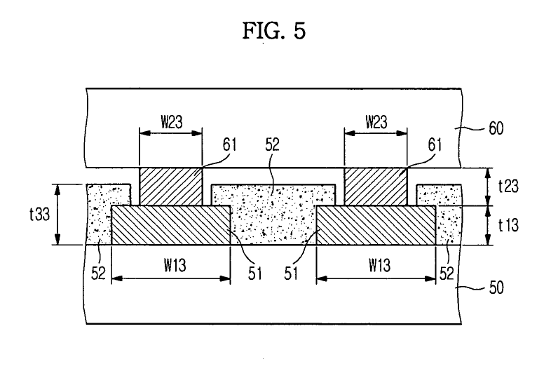

Furthermore, according to the first exemplary embodiment, the width W11 of the first electrode terminal 11 and the width W21 of the second electrode terminal 21 are substantially the same. However, the present invention is not limited to this. According to a third exemplary embodiment of the present invention, a width W13 of a first electrode terminal 51 is formed greater than a width W23 of a second electrode terminal 61 such that an upper end of a separation preventing member 52 covers both sides of an upper surface of the first electrode terminal 51 as shown in FIG. 5. Therefore, while the first electrode terminals 51 and the second electrode terminals 61 are being ultrasonic-welded to each other, although a first PCB 50 and a second PCB 60 laterally move relative to each other within a predetermined range, bonding and connection between the plurality of first electrode terminals 51 and second electrode terminals 61 can be stably achieved.

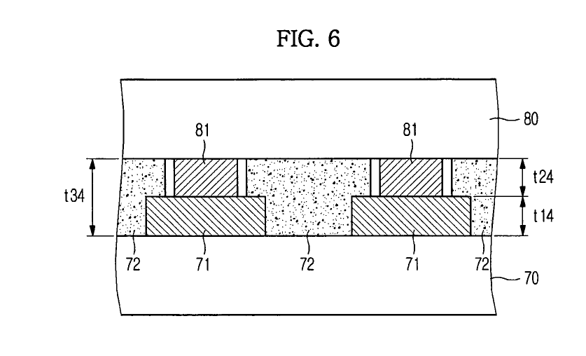

In the third exemplary embodiment, a thickness t33 of the separation preventing member 52 is formed to be greater than a thickness t13 of the first electrode terminal 51 but less than the sum of the thickness t13 of the first electrode terminal 51 and a thickness t23 of the second electrode terminal 61. However, according to a fourth exemplary embodiment of the present invention as shown in FIG. 6, the PCB assembly may be structured in the manner that a thickness t34 of a separation preventing member 72 is substantially the same as the sum of a thickness t14 of a first electrode terminal 71 and a thickness t24 of a second electrode terminal 81. Therefore, in the operation of bonding the plurality of electrode terminals of the pair of PCBs to each other by ultrasonic welding (S40), an upper end of the separation preventing member 72 is bonded to a lower surface of the second PCB 80 such that a first PCB 70 and the second PCB 80 are fixed to each other through the separation preventing members 72. Consequently, bonding and connection between the first and the second electrode terminals 71 and 81 can be more stably maintained.

As can be appreciated from the above description, the PCB assembly according to the exemplary embodiments of the present invention is equipped with separation preventing members projecting from among the plurality of first electrode terminals to enter among the plurality of second electrode terminals, such that the first and the second electrode terminals are not moved relative to each other. According to this, the plurality of first and second electrode terminals can be bonded exactly corresponding to each other without deviating from the correct positions.

Additionally, in the PCB assembly according to the exemplary embodiments of the present invention, since the first and the second electrode terminals are bonded exactly to each other through ultrasonic welding, the bonded surface area can be maximized, thereby preventing deterioration of durability at the bonded part and restraining increase of electric resistance.

Furthermore, arrangement of the first and the second electrode terminals can be performed with ease by help of the separation preventing members. As a result, productivity can be enhanced.

Although a few exemplary embodiments have been shown and described, it would be appreciated by those skilled in the art that changes may be made in these exemplary embodiments without departing from the principles and spirit of the invention, the scope of which is defined in the claims and their equivalents.

What is claimed is:

1. A printed circuit board (PCB) assembly comprising:
a first PCB on which a plurality of first electrode terminals are arranged at intervals from one another;
a second PCB on which a plurality of second electrode terminals are arranged at intervals from one another; and
a separation preventing member which prevents the first and the second electrode terminals from deviating from their correct positions when the first and the second electrode terminals are ultrasonically welded to each other.

2. The PCB assembly according to claim 1, wherein the separation preventing member is projected from at least one of the first PCB among the plurality of first electrode terminals and the second PCB among the plurality of second electrode terminals, to be inserted in at least one of spaces among the second electrode terminals and spaces among the first electrode terminals.

3. The PCB assembly according to claim 2, wherein thickness of the separation preventing member is greater than thickness of the first electrode terminal but less than the sum of the thickness of the first electrode terminal and thickness of the second electrode terminal.

4. The PCB assembly according to claim 2, wherein the thickness of the separation preventing member is the same as the sum of the thickness of the first electrode terminal and the thickness of the second electrode terminal.

5. The PCB assembly according to claim 2, wherein width of first electrode terminal is greater than width of second electrode terminal.

6. The PCB assembly according to claim 5, wherein the separation preventing member partially covers both upper sides of two neighboring first electrode terminals with respect to a width direction.

7. The PCB assembly according to claim 2, wherein the width of the separation preventing member is the same as the interval between respective two neighboring first electrode terminals.

8. The PCB assembly according to claim 2, wherein the width of the separation preventing member is less than the interval between two neighboring first electrode terminals so that the separation preventing member is spaced apart from lateral sides of two neighboring first electrode terminals.

9. The PCB assembly according to claim 1, wherein the separation preventing member is bonded to any one of the first PCB and the second PCB through ultrasonic welding.

10. A manufacturing method for a printed circuit board (PCB) assembly comprising:
forming a plurality of electrode terminals on each of a pair of PCBs;
forming a separation preventing member on the first PCB among the first electrode terminals or the second PCB among the second electrode terminals;
superposing the pair of PCBs on each other; and
bonding the plurality of electrode terminals formed on the pair of PCBs to each other through ultrasonic welding.

11. The manufacturing method according to claim 10, wherein, during the forming of the electrode terminals on the pair of PCBs, a plurality of first electrode terminals are formed on a first PCB at intervals from one another and a plurality of second electrode terminals are formed on a second PCB at intervals from one another.

12. The manufacturing method according to claim 11, wherein the width of the separation preventing member is the same as the interval between respective two neighboring first electrode terminals.

13. The manufacturing method according to claim 11, wherein the width of the separation preventing member is less than the interval between two neighboring first electrode terminals so that the separation preventing member is spaced apart from lateral sides of two neighboring first electrode terminals.

14. The manufacturing method according to claim 10, wherein thickness of the separation preventing member is greater than thickness of the first electrode terminal but less than the sum of the thickness of the first electrode terminal and thickness of the second electrode terminal.

15. The manufacturing method according to claim 10, wherein the thickness of the separation preventing member is the same as the sum of thickness of the first electrode terminal and thickness of the second electrode terminal.

16. The manufacturing method according to claim 10, wherein width of first electrode terminal is greater than width of second electrode terminal.

17. The manufacturing method of claim 16, wherein the separation preventing member partially covers both upper sides of neighboring first electrode terminals with respect to a width direction.

18. The manufacturing method according to claim 10, wherein thickness of the separation preventing member is the same as the sum of thickness of the first electrode terminal and thickness of the second electrode terminal, and wherein, during the bonding of the electrode terminals through ultrasonic welding, the separation preventing member is bonded to any one of the first PCB and the second PCB through ultrasonic welding.

19. A manufacturing method for a printed circuit board (PCB) assembly comprising:
forming at least one separation preventing member on a first PCB among first electrode terminals or a second PCB among second electrode terminals;
superposing the first and second PCBs on each other; and
bonding the plurality of electrode terminals formed on the pair of PCBs to each other through ultrasonic welding.

20. A printed circuit board (PCB) assembly comprising:
a first PCB on which a plurality of first electrode terminals are arranged at intervals from one another;
a second PCB on which a plurality of second electrode terminals are arranged at intervals from one another; and
a plurality of separation preventing members which prevent the first and the second electrode terminals from deviating from their correct positions when the first and the second electrode terminals are ultrasonically welded to each other.
